(19) United States
(12) Patent Application Publication
(10) Pub. No.: US 2023/0102875 A1
(43) Pub. Date: Mar. 30, 2023

(54) MANUFACTURING METHOD OF SEMICONDUCTOR DEVICE

(71) Applicant: GLC SEMI CONDUCTOR GROUP (SH) CO., LTD., Shanghai (CN)

(72) Inventors: Chi-Ching Pu, Hsinchu County (TW); Shun-Min Yeh, Hsinchu City (TW)

(73) Assignee: GLC SEMI CONDUCTOR GROUP (SH) CO., LTD., Shanghai (CN)

(21) Appl. No.: 17/500,911

(22) Filed: Oct. 13, 2021

(30) Foreign Application Priority Data
Sep. 28, 2021 (CN) 202111143022.X

(51) Int. Cl. H01L 23/00; H01L 21/683; H01L 21/48; H01L 21/56

(52) U.S. Cl. CPC H01L 24/19; H01L 24/20; H01L 21/6835; H01L 21/4853; H01L 21/565; H01L 2221/6835; H01L 2224/214

(57) ABSTRACT

A manufacturing method of a semiconductor device includes the following steps. A semiconductor structure is formed on a first surface of a silicon substrate. The semiconductor structure has a first surface facing the silicon substrate. At least one outer circuit is bonded to the semiconductor structure. A molding compound layer is formed covering a second surface of the silicon substrate. A part of the molding compound layer is removed for exposing the silicon substrate. The silicon substrate is removed for exposing the first surface of the semiconductor structure.

### BACKGROUND OF THE INVENTION

### 1. Field of the Invention

The present invention relates to a manufacturing method of a semiconductor device, and more particularly, to a manufacturing method of a semiconductor device including removing a silicon substrate.

### 2. Description of the Prior Art

Because of the semiconductor characteristics, III-V semiconductor compounds may be applied in many kinds of integrated circuit devices, such as high power field effect transistors, high frequency transistors, or high electron mobility transistors (HEMTs). In recent years, gallium nitride (GaN) based materials have been applied in the high power and high frequency products because of the properties of wider band-gap and high saturation velocity. Two-dimensional electron gas (2DEG) may be generated by the piezoelectricity property of the GaN-based materials, and the switching speed may be enhanced because of the higher electron mobility and the higher carrier density of the 2DEG. Generally, the silicon wafer is used as a loading and/or supporting material in the related manufacturing processes of the III-V compound semiconductor unit, and the silicon wafer may be removed after the manufacturing processes of III-V compound semiconductor unit are completed for enhancing the electrical characteristics of the III-V compound semiconductor unit. However, after the silicon wafer is removed, there will be difficulties in subsequent packaging procedure and/or testing procedure, which are not conducive to the overall process and mass production of the related products.

### SUMMARY OF THE INVENTION

It is one of the objectives of the present invention to provide a manufacturing method of a semiconductor device. After bonding an outer circuit to a semiconductor structure, the silicon substrate is removed using a molding compound layer with ability to fix and protect other components. The manufacturing yield may be enhanced and/or the feasibility of mass production may be increased accordingly.

A manufacturing method of a semiconductor device is provided in an embodiment of the present invention. The manufacturing method includes the following steps. A semiconductor structure is formed on a first surface of a silicon substrate. The semiconductor structure has a first surface facing the silicon substrate. At least one outer circuit is bonded to the semiconductor structure. A molding compound layer is formed covering a second surface of the silicon substrate. A part of the molding compound layer is removed for exposing the silicon substrate. The silicon substrate is removed for exposing the first surface of the semiconductor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic drawings illustrating a manufacturing method of a semiconductor device according to an embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7.

FIG. 9 is a schematic drawing illustrating a manufacturing method of a semiconductor device according to another embodiment of the present invention.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

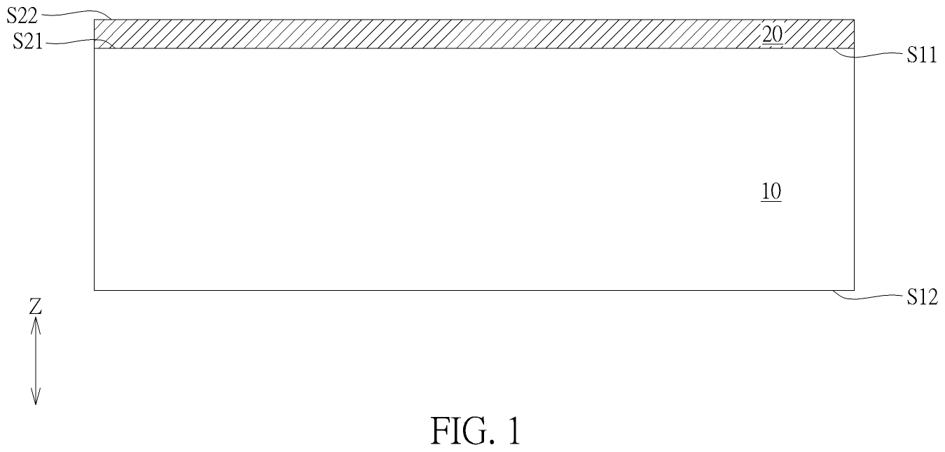

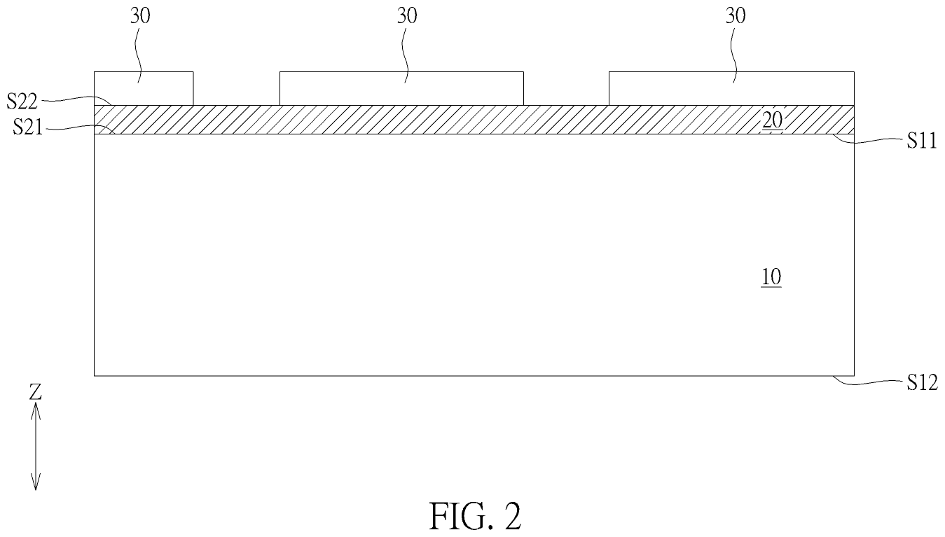

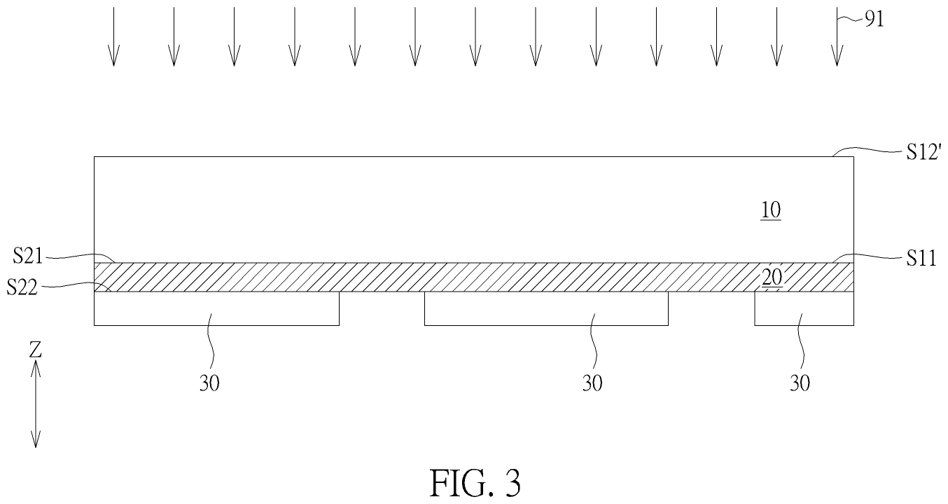

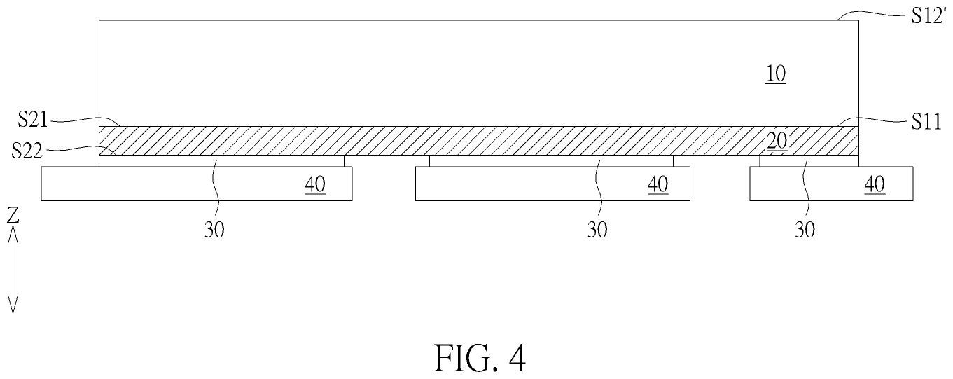

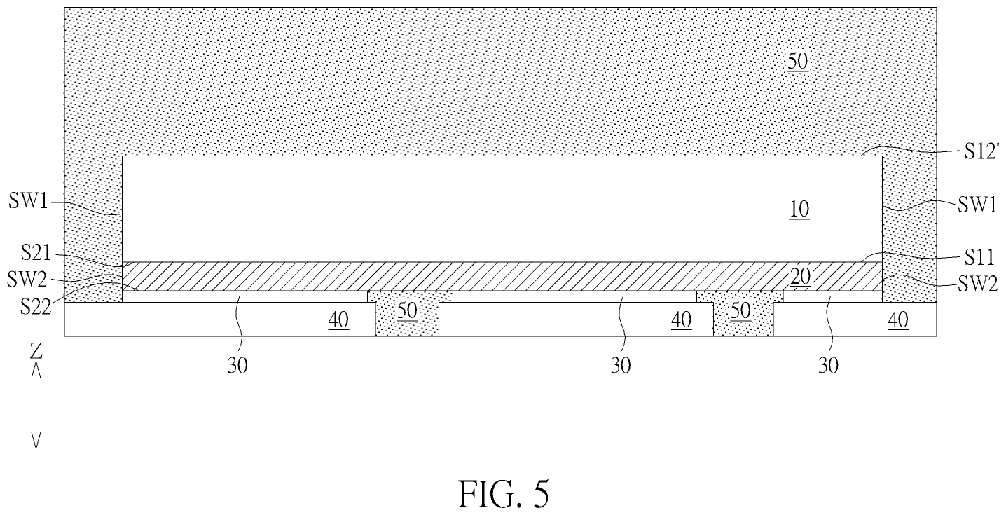

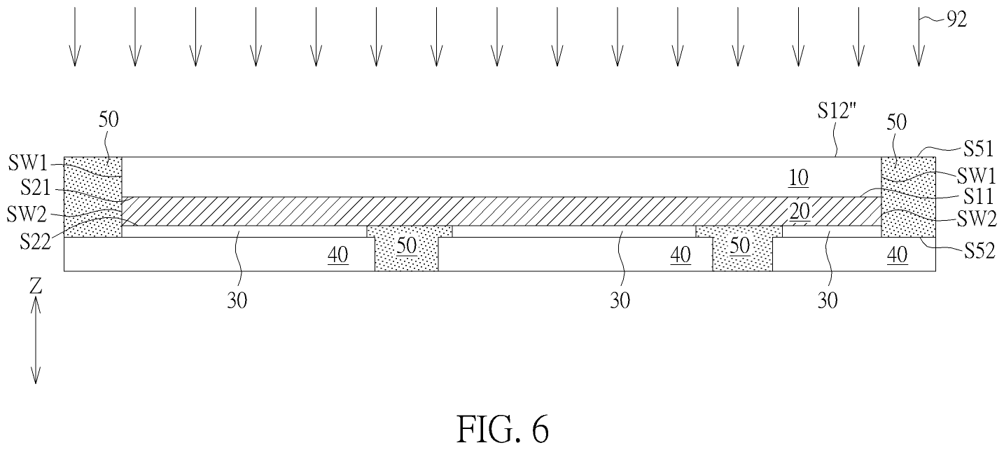

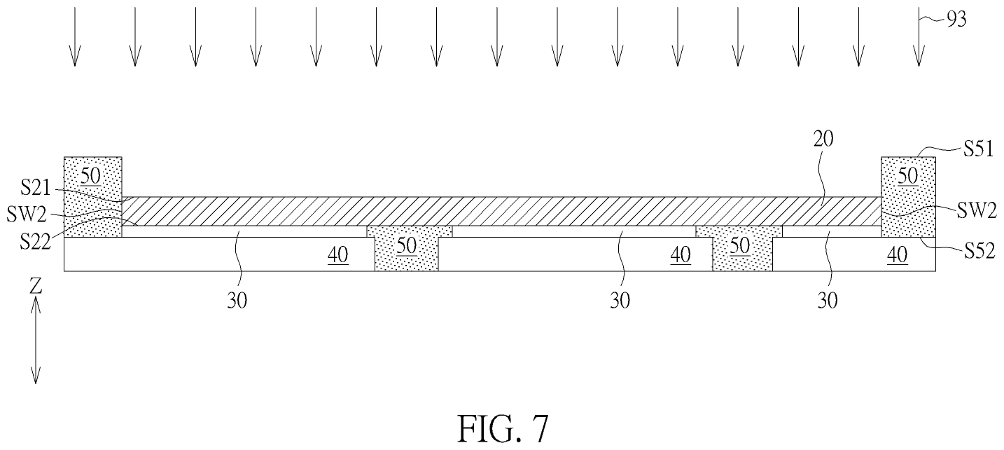

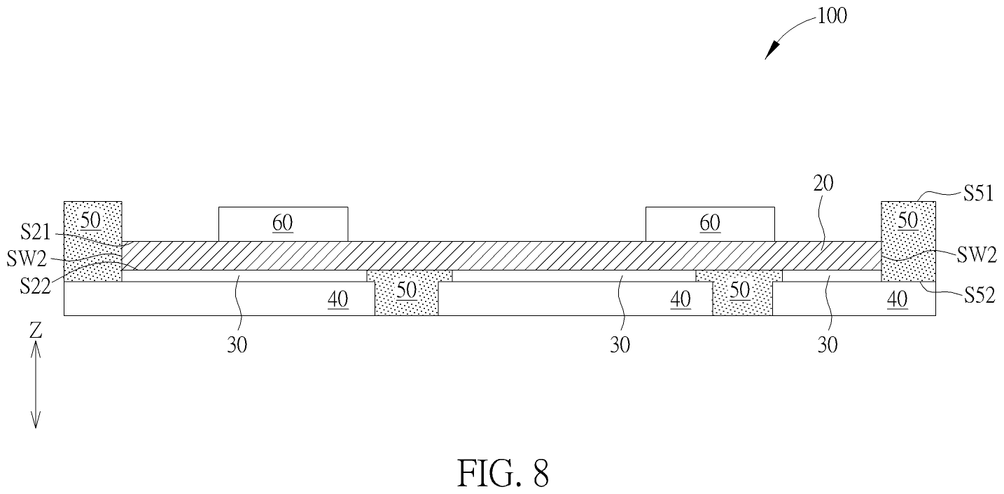

Please refer to FIGS. 1-8. FIGS. 1-8 are schematic drawings illustrating a manufacturing method of a semiconductor device according to an embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, and FIG. 8 is a schematic drawing in a step subsequent to FIG. 7. A manufacturing method of a semiconductor device is provided in this embodiment and includes the following steps. Firstly, as shown in FIG. 1, a silicon substrate 10 is provided. In some embodiments, the silicon substrate 10 may have a first surface S11 and a second surface S12 opposite to the first surface S11 in a vertical direction Z, and the vertical direction Z may be regarded as a thickness direction of the silicon substrate 10 and/or being parallel with the thickness direction of the silicon substrate 10. Therefore, the first surface S11 and the second surface S12 of the silicon substrate 10 are two opposite surfaces of the silicon substrate 10 in the vertical direction Z. Subsequently, a semiconductor structure 20 is formed on the first surface S11 of the silicon substrate 10. In some embodiments, the semiconductor structure 20 may include a III-V compound semiconductor structure or other suitable semiconductor structures. For example, when the semiconductor structure 20 includes a III-V compound semiconductor structure, the semiconductor structure 20 may include stacked material layers (not shown), such as a buffer layer, a III-V compound semiconductor layer, and a III-V compound barrier layer, a gate structure, a source structure, and a drain structure for constituting a III-V compound semiconductor unit (such as a transistor), and there may be connection circuits disposed corresponding to the III-V compound semiconductor unit and/or other types of active devices and/or passive devices in the semiconductor structure 20 according to some design considerations, but not limited thereto. The semiconductor structure 20 may have a first surface S21 and a second surface S22. The first surface S21 and the second surface S22 of the semiconductor structure 20 may be two opposite surfaces of the semiconductor structure 20 in the vertical direction Z. The first surface S21 may face the silicon substrate 10, and the second surface S22 may face away from the silicon substrate 10.

As shown in FIG. 2, at least one connection bump 30 may be formed on the second surface S22 of the semiconductor structure 20. The connection bump 30 may include a solder bump or other suitable connection bump structures, and the material of the connection bump may include gold, copper, tin, lead, or other suitable electrically conductive materials. In some embodiments, the connection bump may be used to bond an outer circuit to the semiconductor structure 20, and the outer circuit may be electrically connected to the unit (such as the transistor described above) in the semiconductor structure 20 via the connection bump 30. In some embodiments, a plurality of connection bumps 30 may be formed on the second surface S22 of the semiconductor structure 20 for bonding outer circuits, but not limited thereto.

As shown in FIG. 3 and FIG. 4, the silicon substrate 10 may be turned over so that the connection bumps may face downwards, one or a plurality of outer circuits 40 may be bonded to the semiconductor structure 20, and the outer circuit 40 may be bonded to the semiconductor structure 20 via the corresponding connection bumps 30. In some embodiments, the semiconductor structure 20 may be regarded as a chip, and the bonding approach described above may be regarded as a flip chip process, but not limited thereto. In some embodiments, the outer circuit 40 illustrated in FIG. 4 and the subsequent figures may include a pin of a lead frame or a portion of other outer circuits, but not limited thereto. Therefore, the outer circuit 40 may be regarded as being located on the second surface S22 of the semiconductor structure 20 and/or located on a side of the second surface S22 of the semiconductor structure 20. Additionally, in some embodiments, a thinning process 91 may be performed to the silicon substrate 10 after the step of forming the connection bumps 30 and before the step of bonding the outer circuit 40 to the semiconductor structure 20, so as to remove a part of the silicon substrate 10 and reduce the thickness of the silicon substrate 10. In some embodiments, the thinning process 91 may include a polishing process or other suitable thinning approaches performed to the silicon substrate 10. The above-mentioned second surface S12 of the silicon substrate 10 may become a second surface S12′ after the thinning process 91, and the first surface S11 and the second surface S12′ may be two opposite surfaces of the silicon substrate 10 in the vertical direction Z. Additionally, in some embodiments, a saw singulation process may be carried out after the thinning process 91 and before the step of bonding the outer circuit 40 to the semiconductor structure 20 according to some design considerations, so as to cut the structure into units for subsequent packaging processes, but not limited thereto.

As shown in FIG. 5, a molding compound layer 50 may be formed covering the second surface S12′ of the silicon substrate 10. In some embodiments, the molding compound layer 50 may further cover sidewalls SW1 of the silicon substrate 10 and sidewalls SW2 of the semiconductor structure 20 in a horizontal direction (such as a direction orthogonal to the vertical direction Z), and another portion of the molding compound layer 50 may be formed between the connection bumps 30 located adjacent to each other for providing packaging effect. In some embodiments, the material of the molding compound layer 50 may include a polymer material, a resin material, an epoxy material, benzocyclobutene (BCB), polyimide (PI), silicon oxide, or other suitable insulation materials with high electrical resistivity and/or low dielectric constant.

As shown in FIG. 5 and FIG. 6, a part of the molding compound layer 50 may be removed for exposing the silicon substrate 10. In some embodiments, the approach configured to remove the part of the molding compound layer 50 for exposing the silicon substrate 10 may include a polishing process 92 or other suitable methods. For example, the polishing process 92 may be carried out at a side of the second surface S12′ of the silicon substrate 10 and performed to the molding compound layer 50 for removing a part of the molding compound layer 50 so as to expose the silicon substrate 10. In some embodiments, a part of the silicon substrate 10 may be removed by the polishing process 92 also, and the above-mentioned second surface S12′ of the silicon substrate 10 may become the second surface S12″ after the polishing process 92, but not limited thereto. In addition, during the polishing process 92, the sidewalls SW2 of the semiconductor structure 20 may be surrounded by the molding compound layer 50 for protecting the semiconductor structure 20 and the semiconductor units in the semiconductor structure 20 during the polishing process 92, and the sidewalls SW1 of the silicon substrate 10 and the sidewalls SW2 of the semiconductor structure 20 may still be surrounded by the molding compound layer 50 after the step of removing a part of the molding compound layer 50 for exposing the silicon substrate 10. In some embodiments, the molding compound layer 50 located on the sidewalls SW1 of the silicon substrate 10 and the sidewalls SW2 of the semiconductor structure 20 may have a first surface S51 and a second surface S52 opposite to the first surface S51 in the vertical direction Z after the polishing process 92. The second surface S12″ of the silicon substrate 10 and the first surface S51 of the molding compound layer 50 may be substantially coplanar after the polishing process 92, and the second surface S52 of the molding compound layer 50 may be connected with the outer circuit 40, but not limited thereto.

As shown in FIG. 6 and FIG. 7, after the polishing process 92, a removing process 93 may be carried out so as to remove the silicon substrate 10 for exposing the first surface S21 of the semiconductor structure 20. In some embodiments, the removing process 93 may include a chemical etching process or other etching approaches with high etching selectivity (such as having higher etching rate to the silicon substrate 10 and does not have any etching effect to the molding compound layer 50 and the semiconductor structure 20 or just have a slight etching reaction and/or other slight chemical reactions with the molding compound layer 50 and the semiconductor structure 20), so as to completely remove the silicon substrate 10 by the removing process 93 and reduce negative influence of the removing process 93 on the molding compound layer 50 and/or the semiconductor structure 20. In addition, during the step of removing the silicon substrate 10, the sidewalls SW2 of the semiconductor structure 20 may be surrounded by the molding compound layer 50 for protecting the semiconductor structure 20 and the semiconductor units disposed therein. Therefore, the polishing process 92 described above may be used to remove only a part of the silicon substrate 10, the required process time of the removing process 93 may be reduced relatively, and the negative influences on the molding compound layer 50 and the semiconductor structure 20 may be reduced and/or avoided accordingly. In addition, the polishing process 92 may be kept from directly damaging the semiconductor structure 20 because only a part of the silicon substrate 10 is removed by the polishing process 92. Therefore, after the step of completely removing the silicon substrate 10 by the removing process 93 for exposing the first surface S21 of the semiconductor structure 20, the sidewalls SW2 of the semiconductor structure 20 may be still surrounded by the molding compound layer 50, and the first surface S51 of the molding compound layer 50 may be higher than the first surface S21 of the semiconductor structure 20 in the vertical direction Z. Additionally, in some embodiments, a saw singulation process may be carried out after the polishing process 92 and before the removing process 93 according to some design considerations, so as to cut the structure into units separated from one another, but not limited thereto. By the manufacturing method of the present invention, the molding compound layer 50 used in the packaging process may be used to provide the fixing effect and the protection effect in the process of removing the silicon substrate 10. The manufacturing yield may be enhanced and/or the feasibility of mass production may be increased accordingly.

As shown in FIG. 7 and FIG. 8, after the step of removing the silicon substrate 10, a redistribution layer (RDL) structure 60 may be formed on the first surface S21 of the semiconductor structure 20. The redistribution layer structure 60 may be regarded as a backside redistribution layer structure for being electrically connected with the unit (such as the transistor described above) in the semiconductor structure 20 and/or being electrically connected to the outer circuit 40 via the connection circuit (not shown) in the semiconductor structure 20 and the connection bump 30, and a vertical structure extending in the vertical direction Z may be formed accordingly. As shown in FIG. 8, the semiconductor device 100 formed by the manufacturing method described above may include the semiconductor structure 20, the connection bumps 30, the outer circuits 40, and the molding compound layer 50. The connection bumps 30 and the outer circuits 40 may be disposed on the second surface S22 of the semiconductor structure 20, and the redistribution layer structure 60 may be disposed on the first surface S21 of the semiconductor structure 20. In other words, the outer circuit 40 and the redistribution layer structure 60 may be disposed on the two opposite sides of the semiconductor structure 20 in the vertical direction Z, respectively, and the outer circuit 40 may transmit signals via the circuit in the semiconductor structure 20 and/or the redistribution layer structure 60. In addition, the molding compound layer 50 may surround the sidewalls SW2 of the semiconductor structure 20 in the horizontal direction, and the first surface S51 of the molding compound layer 50 may be higher than the first surface S21 of the semiconductor structure 20 in the vertical direction Z.

The following description will detail the different embodiments of the present invention. To simplify the description, identical components in each of the following embodiments are marked with identical symbols. For making it easier to understand the differences between the embodiments, the following description will detail the dissimilarities among different embodiments and the identical features will not be redundantly described.

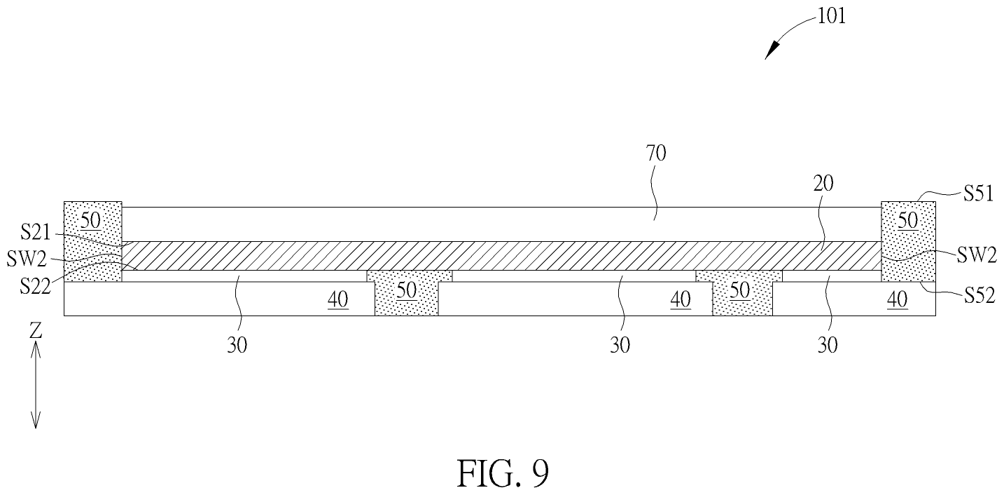

Please refer to FIG. 9, FIG. 6, and FIG. 7. FIG. 9 is a schematic drawing illustrating a manufacturing method of a semiconductor device 101 according to another embodiment of the present invention. In some embodiments, FIG. 9 may be regarded as a schematic drawing in a step subsequent to FIG. 7, but not limited thereto. As shown in FIG. 6, FIG. 7, and FIG. 9, in some embodiments, after the step of removing the silicon substrate 10, a filling material 70 may be formed on the first surface S21 of the semiconductor structure 20, and the filling material 70 may include a metallic thin film, a ceramic thin film, a high thermal conductivity polymer material, or other materials capable of enhancing the device characteristics of the semiconductor device 101. In addition, the filling material 70 may be formed by deposition or other suitable approaches. In some embodiments, the filling material 70 may be formed after the step of forming the redistribution layer structure 60 shown in FIG. 8 described above, and the filling material 70 may cover the redistribution layer structure 60 also, but not limited thereto.

To summarize the above descriptions, according to the manufacturing method of the semiconductor device in the present invention, the packaging process may be performed first, and the molding compound layer used in the packaging process may be used to provide the fixing and supporting effect and the protection effect required during the process of removing the silicon substrate. The manufacturing yield may be enhanced and/or the feasibility of mass production may be increased accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device, comprising:
forming a semiconductor structure on a first surface of a silicon substrate, wherein the semiconductor structure has a first surface facing the silicon substrate;
bonding at least one outer circuit to the semiconductor structure;
forming a molding compound layer covering a second surface of the silicon substrate;
removing a part of the molding compound layer for exposing the silicon substrate; and
removing the silicon substrate for exposing the first surface of the semiconductor structure.

2. The manufacturing method of the semiconductor device according to claim 1, wherein the first surface of the silicon substrate and the second surface of the silicon substrate are two opposite surfaces of the silicon substrate in a vertical direction.

3. The manufacturing method of the semiconductor device according to claim 2, wherein the vertical direction is parallel with a thickness direction of the silicon substrate.

4. The manufacturing method of the semiconductor device according to claim 1, wherein the silicon substrate is removed completely by an etching approach.

5. The manufacturing method of the semiconductor device according to claim 1, wherein the at least one outer circuit is located on a second surface of the semiconductor structure.

6. The manufacturing method of the semiconductor device according to claim 5, wherein the first surface of the semiconductor structure and the second surface of the semiconductor structure are two opposite surfaces of the semiconductor structure in a vertical direction.

7. The manufacturing method of the semiconductor device according to claim 5, further comprising:
forming connection bumps on the second surface of the semiconductor structure, wherein the at least one outer circuit is bonded to the semiconductor structure via the connection bumps.

8. The manufacturing method of the semiconductor device according to claim 7, further comprising:
performing a thinning process to the silicon substrate after the step of forming the connection bumps and before the step of bonding the at least one outer circuit to the semiconductor structure so as to remove a part of the silicon substrate and reduce a thickness of the silicon substrate.

9. The manufacturing method of the semiconductor device according to claim 7, wherein a portion of the molding compound layer is formed between the connection bumps located adjacent to each other.

10. The manufacturing method of the semiconductor device according to claim 1, wherein an approach configured to remove the part of the molding compound layer for exposing the silicon substrate comprises a polishing process.

11. The manufacturing method of the semiconductor device according to claim 10, wherein a part of the silicon substrate is removed by the polishing process.

12. The manufacturing method of the semiconductor device according to claim 10, wherein a surface of the silicon substrate and a surface of the molding compound layer are coplanar after the polishing process and before the step of removing the silicon substrate.

13. The manufacturing method of the semiconductor device according to claim 1, wherein the molding compound layer further covers sidewalls of the silicon substrate.

14. The manufacturing method of the semiconductor device according to claim 13, wherein the sidewalls of the silicon substrate is covered by the molding compound layer after the step of removing the part of the molding compound layer for exposing the silicon substrate.

15. The manufacturing method of the semiconductor device according to claim 1, wherein the molding compound layer further covers sidewalls of the semiconductor structure.

16. The manufacturing method of the semiconductor device according to claim 15, wherein the sidewalls of the semiconductor structure are surrounded by the molding compound layer during the step of removing the silicon substrate.

17. The manufacturing method of the semiconductor device according to claim 15, wherein the sidewalls of the semiconductor structure are surrounded by the molding compound layer after the step of removing the silicon substrate for exposing the first surface of the semiconductor structure.

18. The manufacturing method of the semiconductor device according to claim 1, further comprising:
forming a redistribution layer (RDL) structure on the first surface of the semiconductor structure after the step of removing the silicon substrate.

19. The manufacturing method of the semiconductor device according to claim 1, further comprising:
forming a filling material on the first surface of the semiconductor structure after the step of removing the silicon substrate.

20. The manufacturing method of the semiconductor device according to claim 1, wherein the semiconductor structure comprises a III-V compound semiconductor structure.
